(19) United States
(12) Patent Application Publication
(10) Pub. No.: US 2016/0013049 A1
(43) Pub. Date: Jan. 14, 2016

(54) ENHANCING UV COMPATIBILITY OF LOW K BARRIER FILM

(71) Applicant: APPLIED MATERIALS, INC., Santa Clara, CA (US)

(72) Inventors: Weifeng YE, San Jose, CA (US); Mei-yee SHEK, Palo Alto, CA (US); Mihaela BALSEANU, Cupertino, CA (US); Xiaojun ZHANG, Fremont, CA (US); Xiaolan BA, San Jose, CA (US); Yu JIN, Santa Clara, CA (US); Li-Qun XIA, Cupertino, CA (US)

(73) Assignee: APPLIED MATERIALS, INC., Santa Clara, CA (US)

(21) Appl. No.: 14/770,641

(22) PCT Filed: Feb. 18, 2014
(86) PCT No.: PCT/US2014/016831

§ 371 Date: Aug. 26, 2015

Related U.S. Application Data
(60) Provisional application No. 61/782,654, filed on Mar. 14, 2013.

(51) Int. Cl. H01L 21/02

(52) U.S. Cl. CPC H01L 21/02274; H01L 21/02211; H01L 21/02219

(57) ABSTRACT

Embodiments of the present invention generally relate to a method for forming a dielectric barrier layer. The dielectric barrier layer is deposited over a substrate by a plasma enhanced deposition process. In one embodiment, a gas mixture is introduced into a processing chamber. The gas mixture includes a silicon-containing gas, a nitrogen-containing gas, a boron-containing gas, and argon (Ar) gas.

### BACKGROUND

1. Field

Embodiments of the present invention generally relate to a method for forming a dielectric barrier layer.

2. Description of the Related Art

Semiconductor device geometries have dramatically decreased in size since their introduction several decades ago. Modern semiconductor fabrication equipment routinely produces devices with 90 nm, 65 nm, and 45 nm feature sizes, and new equipment is being developed and implemented to make devices with even smaller geometries. The smaller sizes, however, mean device elements have to work closer together which can increase the chances of electrical interference, including cross-talk and parasitic capacitance.

To reduce the degree of electrical interference, dielectric insulating materials, also called interlayer dielectric (ILD), are used to fill the gaps, trenches, and other spaces between the device elements, metal lines, and other device features. The dielectric materials are chosen for their ease of formation in the spaces between device features, and their low dielectric constants (i.e., “k-values”). Dielectrics with lower k-values are better at minimizing cross-talk and resistive-capacitive (RC) delays, as well as reducing the overall power consumption of the device.

In some applications, the dielectric materials may be exposed to UV irradiation. UV irradiation may affect the dielectric material's chemical structure and thus change the physical and electrical properties of the materials. For example, UV is frequently used to lower the dielectric constant of ILD layer. However, the UV treatment may have undesirable effects on the adjacent dielectric layer, such as the dielectric barrier layer. The dielectric barrier layer may be generally weakened by the UV treatment and may undergo stress change from compressive to tensile during the UV treatment, which may lead to peeling. In addition, such indirect UV treatment may degrade the dielectric barrier layer's dielectric breakdown properties, which may lead to high leakage current and low voltage breakdown of dielectric (VBD).

Therefore, an improved method for forming a UV compatible dielectric barrier layer with low dielectric constant is needed.

### SUMMARY

Embodiments of the present invention generally relate to a method for forming a dielectric barrier layer. The dielectric barrier layer is deposited over a substrate by a plasma enhanced deposition process. In one embodiment, a gas mixture is introduced into a processing chamber. The gas mixture includes a silicon-containing gas, a nitrogen-containing gas, a boron-containing gas, and argon (Ar) gas.

In one embodiment, a method for forming a barrier layer on a substrate is disclosed. The method includes delivering a mixture of gases into a processing chamber, and the mixture of gases comprises a silicon: containing gas, a nitrogen-containing gas, and Ar gas: The method further includes generating a plasma inside the processing chamber and depositing the barrier layer on the substrate. The barrier layer has a change in stress of about 200 Mpa or less after a UV treatment.

In another embodiment, a method for forming a barrier layer on a substrate is disclosed. The method includes delivering a mixture of gases into a processing chamber, and the mixture of gases comprises a silicon-containing gas, a nitrogen-containing gas, a boron-containing gas, and Ar gas. The method further includes generating a plasma inside the processing chamber and depositing the barrier layer on the substrate.

In another embodiment, a method for forming a barrier layer on a substrate is disclosed. The method includes delivering a mixture of gases into a processing chamber, and the mixture of gases includes trimethylsilane (TMS), ammonia (NH₃), diborane (B₂H₆), and Ar. The method further includes generating a plasma inside the processing chamber, and depositing a barrier layer on the substrate. The barrier layer has a dielectric constant of about 5.0 or less and a change in stress of about 300 MPa or less after a UV treatment.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional view of a substrate.

FIG. 2 depicts a flow diagram illustrating a method according to an embodiment described herein.

FIG. 3 depicts a flow diagram illustrating a method according to an embodiment described herein.

FIG. 4 is a chart showing k-value and change in stress under different process conditions.

FIG. 5 is a cross sectional schematic diagram of a chemical vapor deposition (CVD) chamber that may be used to perform the methods described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally relate to a method for forming a dielectric barrier layer. The dielectric barrier layer is deposited over a substrate by a plasma enhanced deposition process. In one embodiment, a gas mixture is introduced into a processing chamber. The gas mixture includes a silicon-containing gas, a nitrogen-containing gas, a boron-containing gas, and argon (Ar) gas.

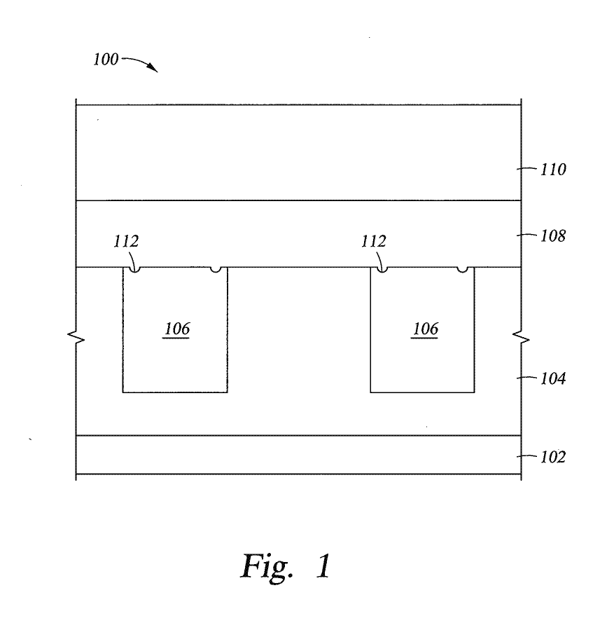

FIG. 1 is a cross-sectional view of a substrate 100. The substrate 100 has an ILD layer 104 disposed over an underlayer 102. Conductive contacts 106 are disposed within the ILD layer 104 and may be separated from the ILD layer 104 by barrier layers (not shown). The conductive contacts 106 may be a metal, such as copper (Cu). The ILD layer 104 contains a dielectric material, such as a low-k dielectric material. In one example, the ILD layer 104 contains a low-k dielectric material, such as a silicon carbide oxide material or a carbon doped silicon oxide material, for example, BLACK DIAMOND® II low-k dielectric material, available from Applied Materials, Inc., located in Santa Clara, Calif. To reduce the k-value, the ILD layer 104 may optionally contain a porogen and then be exposed to UV treatment to form nanopores.

An optional capping layer (not shown) may be selectively deposited over the conductive contacts 106 before depositing a dielectric barrier layer 108 over the ILD layer 104 and the conductive contacts 106. The dielectric barrier layer 108 may be a dielectric material, such as silicon carbon nitride (SiCN) or silicon boron carbon nitride (SiBCN).

As shown in FIG. 1, recesses 112 may be formed at the corners of the conductive contacts 106 after the conductive contacts 106 are deposited into the openings of the ILD layer and processed by chemical mechanical polishing (CMP). The dielectric barrier layer 108, as formed by the methods described therein, may conformally fill the recesses 112.

A second ILD layer 110 may be deposited over the dielectric barrier layer 108 for next metal level. As the ILD layer 110 is treated with UV to reduce the k-value, the dielectric barrier layer 108 may be also affected by being indirectly exposed to UV treatment. To minimize the change in stress and to reduce the k-value of the dielectric barrier layer 108, the following methods of depositing the dielectric barrier layer 108 may be utilized.

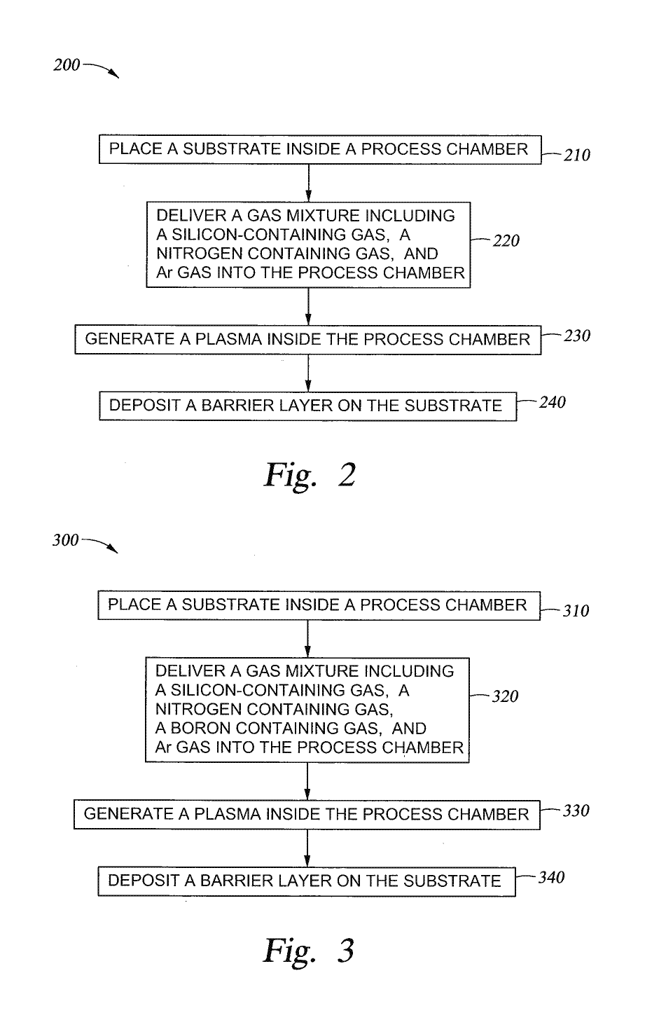

FIG. 2 is a flow diagram of a method 200 according to an embodiment of the invention. The method 200 starts at process 210 by placing a substrate inside a processing chamber. The process chamber may be any suitable processing chamber, such as a chemical vapor deposition (CVD) chamber, a plasma enhanced chemical vapor deposition (PECVD) chamber or an atomic layer deposition (ALD) chamber. The substrate may be a silicon substrate, a III-IV compound substrate, a silicon/germanium (SiGe) substrate, a silicon-on-insulator (SOI) substrate, a display substrate such as a liquid crystal display (LCD), a plasma display, an electro luminescence (EL) lamp display, a light emitting diode (LED) substrate, or an organic light emitting diode (OLED) substrate, for example. In some embodiments, the substrate may be a semiconductor wafer (e.g., a 200 mm, 300 mm, 450 mm, etc. silicon wafer). One or more features may be pre-formed over the substrate. The features may be, for example, transistors, transistor gates, filled trenches or openings, or conductive lines.

As mentioned above, the substrate may have an underlayer 102 and an ILD layer 104 having conductive contacts 106. A chemical mechanical polishing (CMP) process may be performed to planarize the surface prior to depositing the dielectric barrier layer 108 over the ILD layer 104 and the conductive contacts 106.

At process 220, a mixture of gases is delivered into the processing chamber. The mixture of gases may include a silicon-containing gas, a nitrogen-containing gas, and Ar gas. The silicon-containing gas may be bis(diethylamino) silane (BDEAS), hexamethylcyclotrisilazane (HMCTZ), disilylmethane (Bono-2), or trimethylsilane (TMS). The nitrogen-containing gas may be nitrogen gas (N₂), ammonia (NH₃) or hydrazine(H₂N₂).

Ar gas may be used as a carrier gas. It is found that by introducing an argon gas to the plasma and increasing the temperature from about 350 degrees Celsius to about 400 degrees Celsius at a low pressure such as below about 3 Torrs, the dielectric barrier layer may have a reduced stress change after indirect UV treatment. Increasing temperature reduces the hydrogen content in various forms (SiH, NH, and CHₓ) and minimizes changes in the layer. Argon addition increases the ion bombardment and increases the density and hardness of the layer. In one embodiment, the gas mixture includes TMS, NH₃, Ar, and N₂. TMS has a flow rate ranging from about 50 standard cubic centimeters per minute (sccm) to about 300 sccm. NH₃ has a flow rate ranging from about 500 sccm to about 2000 sccm. Ar gas has a flow rate ranging from about 1000 sccm to about 5000 sccm. N₂ has a flow rate ranging from about 500 sccm to about 4000 sccm. Spacing between showerhead to wafer ranges from 250 mil to 500 mil.

At process 230, a plasma is generated inside the processing chamber from the gas mixture described above. The plasma may be generated by applying a power density ranging between about 0.01 W/cm² and about 6.4 W/cm², which is a RF power level of between about 10 W and about 2,000 W, such as between about 100 W and about 400 W at a high frequency between 13 MHz and 14 MHz, such as 13.56 MHz.

At process 240, the dielectric barrier layer is deposited on the substrate from the plasma. The dielectric barrier layer may be a SiCN layer. A second ILD layer may be deposited over the dielectric barrier layer and the ILD layer may be exposed to a UV treatment to reduce the ILD layer's k-value. The dielectric barrier layer may be indirectly exposed to the UV treatment. The SiCN layer has improved UV stability stress control since the change in stress during the indirect UV treatment is about 200 MPa or less.

FIG. 3 is a flow diagram of a method 300 according to another embodiment of the invention. The method 300 starts at process 310 by also placing a substrate inside a processing chamber, as described above. At process 320, a mixture of gases is delivered into the processing chamber. The mixture of gases may include a silicon-containing gas, a nitrogen-containing gas, a boron-containing gas, and Ar gas. The silicon-containing gas may be BDEAS, HMCTZ, Bono-2, or TMS. The nitrogen-containing gas may be N₂, NH₃ or H₂N₂. The boron-containing gas is also included in the gas mixture because boron has a lower polarizability compared to silicon. Thus the addition of boron may reduce the k value but still maintain the barrier properties, such as hermeticity and density, and stress stability after UV treatment. However, the boron concentration may be limited between about 0.1% and about 10%, because boron-nitrogen bond is not stable in oxidizing environment, which the dielectric barrier layer may encounter during subsequent processes. In one embodiment, the boron-containing as is diborane and has a flow rate of greater than 25 sccm, such as 40 sccm. In one embodiment, the gas mixture includes TMS; NH₃, Ar, diborane and N₂.

At process 330, a plasma is generated inside the processing chamber from the gas mixture described above. The plasma may be generated by applying a power density ranging between about 0.01 W/cm² and about 6.4 W/cm², which is a RF power level of between about 10 W and about 2,000 W, such as between about 100 W and about 400 W at a high frequency between 13 MHz and 14 MHz, such as 13.56 MHz.

At process 340, the dielectric barrier layer is deposited on the substrate from the plasma. The dielectric barrier layer may be a SiBCN layer. A second ILD layer may be deposited over the dielectric barrier layer and the ILD layer may be exposed to a UV treatment to reduce the ILD layer's k-value. The dielectric barrier layer may be indirectly exposed to the UV treatment. The SiBCN layer has improved UV stability stress control with stable VBD and no substantial leakage current, while maintaining a low k-value after the indirect UV treatment. In one embodiment, after the dielectric barrier layer is indirectly exposed to UV treatment, the dielectric barrier layer has a k-value of 5.0 or less, a stable VBD at greater than 6 MV/cm, and a change in stress during UV treatment of 300 MPa or less.

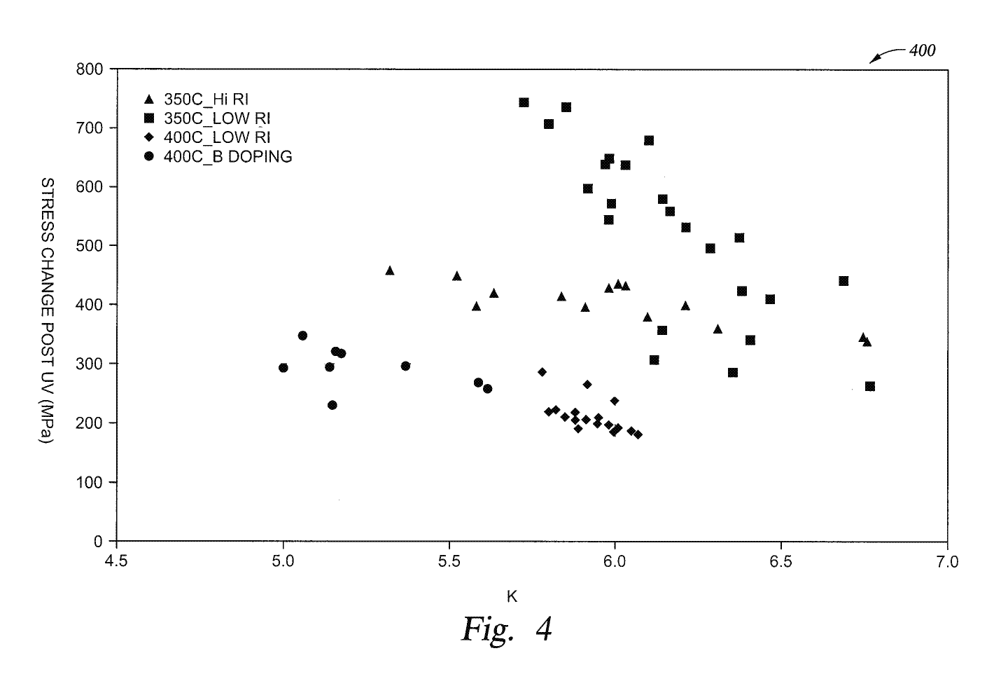

FIG. 4 is a chart 400 showing k-value and change in stress at different process conditions. As a result of adding Ar gas and increasing the temperature from 350 degrees Celsius to 400 degrees Celsius, the change in stress is lowered to about 200 Mpa. The addition of a boron-containing gas lowered the k-value to below 5.8. One data point shows that the k value is at about 5.0.

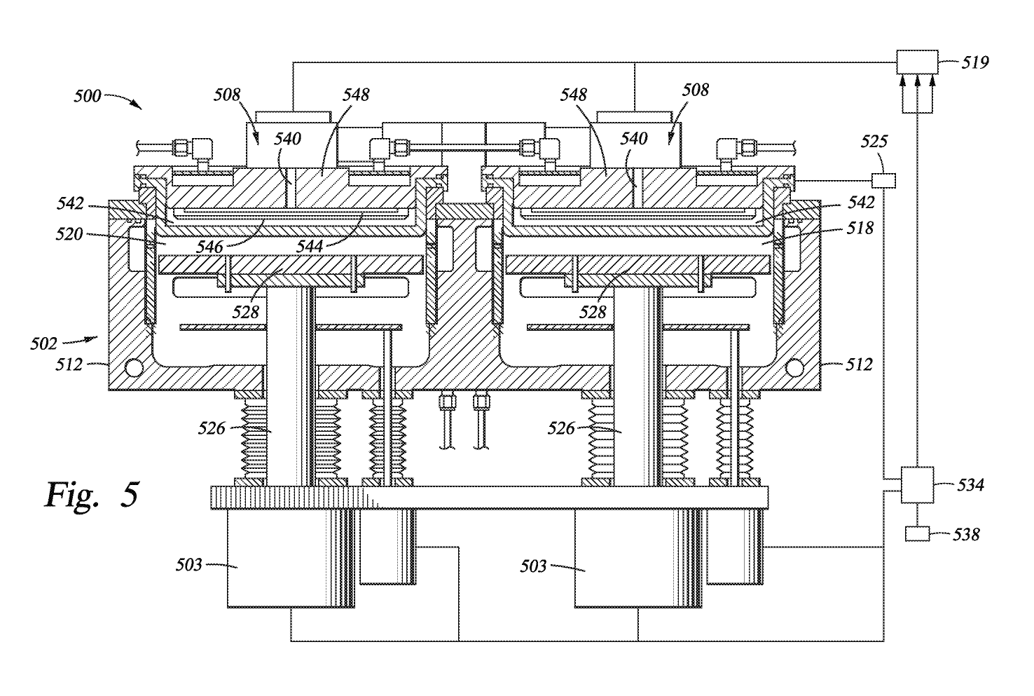

FIG. 5 is a cross sectional schematic diagram of a CVD chamber 500 that may be used for practicing embodiments of the invention. An example of such a chamber is a dual or twin chamber on a PRODUCER® system, available from Applied Materials, Inc. of Santa Clara, Calif. The twin chamber has two isolated processing regions (for processing two substrates, one substrate per processing region) such that the flow rates experienced in each region are approximately one half of the flow rates into the whole chamber. A chamber having two isolated processing regions is further described in U.S. Pat. No. 5,855,681, which is incorporated by reference herein. Another example of a chamber that may be used is a DxZ® chamber on a CENTURA® system, both of which are available from Applied Materials, Inc.

The CVD chamber 500 has a chamber body 502 that defines separate processing regions 518, 520. Each processing region 518, 520 has a pedestal 528 for supporting a substrate (not shown) within the CVD chamber 500. Each pedestal 528 typically includes a heating element (not shown). In one embodiment, each pedestal 528 is movably disposed in one of the processing regions 518, 520 by a stem 526 which extends through the bottom of the chamber body 502 where it is connected to a drive system 503.

Each of the processing regions 518, 520 may include a gas distribution assembly 508 disposed through a chamber lid to deliver gases into the processing regions 518, 520. The gas distribution assembly 508 of each processing region normally includes a gas inlet passage 540 which delivers gas from a gas flow controller 519 into a gas distribution manifold 542, which is also known as a showerhead assembly. Gas flow controller 519 is typically used to control and regulate the flow rates of different process gases into the chamber. Other flow control components may include a liquid flow injection valve and liquid flow controller (not shown) if liquid precursors are used. The gas distribution manifold 542 comprises an annular base plate 548, a face plate 546, and a blocker plate 544 between the base plate 548 and the face plate 546. The gas distribution manifold 542 includes a plurality of nozzles (not shown) through which gaseous mixtures are injected during processing. An RF (radio frequency) source 525 provides a bias potential to the gas distribution manifold 542 to facilitate generation of a plasma between the showerhead assembly 542 and the pedestal 528. During a plasma-enhanced chemical vapor deposition (PECVD) process, the pedestal 528 may serve as a cathode for generating the RF bias within the chamber body 502. The cathode is electrically coupled to an electrode power supply to generate a capacitive electric field in the chamber 500. Typically an RF voltage is applied to the cathode while the chamber body 502 is electrically grounded. Power applied to the pedestal 528 creates a substrate bias in the form of a negative voltage on the upper surface of the substrate. This negative voltage is used to attract ions from the plasma formed in the chamber 500 to the upper surface of the substrate.

During processing, process gases are uniformly distributed radially across the substrate surface. The plasma is formed from one or more process gases or a gas mixture by applying RF energy from the RF power supply 525 to the gas distribution manifold 542, which acts as a powered electrode. Film deposition takes place when the substrate is exposed to the plasma and the reactive gases provided therein. The chamber walls 512 are typically grounded. The RF power supply 525 can supply either a single or mixed-frequency RF signal to the gas distribution manifold 542 to enhance the decomposition of any gases introduced into the processing regions 518, 520.

A system controller 534 controls the functions of various components such as the RF power supply 525, the drive system 503, the lift mechanism, the gas flow controller 519, and other associated chamber and/or processing functions. The system controller 534 executes system control software stored in a memory 538, which in the preferred embodiment is a hard disk drive, and can include analog and digital input/output boards, interface boards, and stepper motor controller boards. Optical and/or magnetic sensors are generally used to move and determine the position of movable mechanical assemblies.

The above CVD system description is mainly for illustrative purposes, and other plasma processing chambers may also be employed for practicing embodiments described herein.

In summary, methods for forming a UV compatible dielectric barrier layer are disclosed. The dielectric barrier is doped with boron and Ar is used as carrier gas. As a result, the dielectric barrier layer has improved UV stability stress control while maintaining the low k-value.

While the foregoing is directed to embodiments of the present invention, other and further embodiments of the invention may be devised without departing from the basic scope thereof, and the scope thereof is determined by the claims that follow.

1. A method for forming a barrier layer on a substrate, comprising:
delivering a mixture of gases into a processing chamber, wherein the mixture of gases comprises a silicon-containing gas, a nitrogen-containing gas, and argon (Ar) gas;
generating a plasma inside the processing chamber; and
depositing the barrier layer on the substrate, wherein the barrier layer has a change in stress of about 200 MPa or less after a UV treatment.

2. The method of claim 1, wherein the silicon-containing gas is trimethylsilane (TMS).

3. The method of claim 1, wherein the silicon-containing gas is hexamethylcyclotrisilazane (HMCTZ).

4. The method of claim 1, wherein the silicon-containing gas is bis(diethylamino) silane (BDEAS).

5. The method of claim 1, wherein the silicon-containing gas is disilylmethane (Bono-2).

6. The method of claim 2, wherein the Ar gas has a flow rate ranging from about 1000 sccm to about 5000 sccm.

7. A method for forming a barrier layer on a substrate, comprising:
delivering a mixture of gases into a processing chamber, wherein the mixture of gases comprises a silicon-containing gas, a nitrogen-containing gas, a boron-containing gas, and Ar gas;
generating a plasma inside the processing chamber; and
depositing the barrier layer on the substrate.

8. The method of claim 7, wherein the silicon-containing gas is TMS.

9. The method of claim 8, wherein the boron-containing gas is diborane.

10. The method of claim 9, wherein a concentration of the boron-containing gas ranges from about 0.1% to about 10%.

11. The method of claim 7, wherein the silicon-containing gas is HMCTZ

12. The method of claim 7, wherein the silicon-containing gas is BDEAS.

13. The method of claim 7, wherein the silicon-containing gas is Bono-2.

14. A method for forming a barrier layer on a substrate, comprising:
delivering a mixture of gases into a processing chamber, wherein the mixture of gases comprises TMS, ammonia (NH₃), diborane and Ar;
generating a plasma inside the processing chamber; and
depositing a barrier layer on the substrate, wherein the barrier layer has a dielectric constant of about 5.0 and a change in stress of about 300 MPa or less after a UV treatment.

15. The method of claim 14, wherein a concentration of the diborane ranges from about 0.1% to about 10%.

16. The method of claim 7, wherein the barrier layer has a dielectric constant of about 5.0 and a change in stress at about 300 MPa or less after a UV treatment.
